(19) United States
(12) Patent Application Publication
(10) Pub. No.: US 2024/0042553 A1
(43) Pub. Date: Feb. 8, 2024

(54) METHOD FOR LASER CUTTING DISPLAY MATERIALS AND DEVICE FOR LASER CUTTING DISPLAY MATERIALS

(71) Applicant: Samsung Display Co., LTD., Yongin-si, Gyeonggi-do (KR)

(72) Inventor: Sang Sun HAN, Asan-si Chungcheongnam-do (KR)

(21) Appl. No.: 18/257,590

(22) PCT Filed: Aug. 19, 2021
(86) PCT No.: PCT/KR2021/011036

§ 371 Date: Jun. 15, 2023

(30) Foreign Application Priority Data
Dec. 18, 2020 (KR) 10-2020-0178678

(51) Int. Cl. B23K 26/38; B23K 26/03; B23K 26/035

(52) U.S. Cl. CPC B23K 26/38; B23K 26/032; B23K 26/035; B23K 2101/36

(57) ABSTRACT

A method for laser cutting display materials includes loading respective display materials from a tray, and a cutting dummy portions of the loaded display materials. The loading operation includes arranging a loader robot in the vicinity of the tray, aligning, at a first teaching point of the display materials, a laser pointer emitted from the loader robot, and picking up the display materials through at least one pickup pad of the loader robot.

This application is a national stage application of International Patent Application No. PCT/KR2021/011036, filed on Aug. 19, 2021, claiming priority to Korean Patent Application No. 10-2020-0178678, filed on Dec. 18, 2020, the content of which in their entirety is herein incorporated by reference.

### 1. FIELD

The disclosure relates to a method and device for laser-cutting display materials.

### 2. BACKGROUND ART

As an information society is being developed, a demand for display devices for displaying images is being diversified. For example, display devices have been applied to various electronic devices such as smart phones, digital cameras, notebook computers, navigation systems, and smart televisions. Here, the display devices may be flat panel display devices such as a liquid crystal display (“LCD”) device, a field emission display (“FED”) device, or an organic light-emitting display (“OLED”) device.

During a fabrication of a display device, a laser cutting of display materials is performed. For a reliable laser cutting process for display materials, the display materials and a cutting device need to be accurately aligned.

### SUMMARY

To address the aforementioned problems, embodiments of the disclosure provide a simplified method of laser-cutting display materials.

Embodiments of the disclosure also provide a simplified device for laser-cutting display materials.

However, embodiments of the disclosure are not restricted to those set forth herein. The above and other embodiments of the disclosure will become more apparent to one of ordinary skill in the art to which the disclosure pertains by referencing the detailed description of the disclosure given below.

In an embodiment of the disclosure, a method of laser-cutting display materials includes a loading operation of loading display materials from a tray. The loading operation includes a loader robot arrangement operation of arranging a loader robot near the tray, an alignment operation of aligning pickup pads of the loader robot with the display materials, and a pickup operation of picking up the display materials with the pickup pads of the loader robot, in the alignment operation, the pickup pads are aligned with the display materials in accordance with the same standard regardless of a size of the display materials, and in the pickup operation, the pickup pads pick up the display materials regardless of center positions of the display materials.

In another embodiment of the disclosure, a device for laser-cutting display materials includes a tray in which display materials are loaded, and a loader robot loading the display materials from the tray. The loader robot includes a laser irradiation part, which irradiates a laser pointer to be aligned with first teaching points of the display materials, and pickup pads, which pick up the display materials.

In another embodiment of the disclosure, a device for laser-cutting display materials includes a tray in which display materials are loaded, a loader robot loading the display materials from the tray, and a pre-alignment device acquiring alignment information regarding the display materials. The loader robot includes pickup pads, which pick up the display materials, a pre-alignment table of the pre-alignment device defined vacuum holes, and when each of the display materials is disposed on the pre-alignment table, the pickup pads overlap with areas where the vacuum holes of the pre-alignment table are defined.

Details of other embodiments of the disclosure are included in the description and the drawings of the disclosure.

By embodiments of the disclosure, laser cutting facilities and processes may be simplified.

It should be noted that the effects of the disclosure are not limited to those described above, and other effects of the disclosure will be apparent from the following description.

### BRIEF DESCRIPTION OF DRAWINGS

FIG. 1 is a flowchart of an embodiment of a method of laser-cutting display materials according to the disclosure;

FIG. 2 is a flowchart of a loading operation of FIG. 1;

FIG. 3 is a plan view of an embodiment of a display material according to the disclosure;

FIG. 4 is a cross-sectional view taken along line I-I′ of FIG. 3;

FIG. 5 is a perspective view illustrating the loading operation of FIG. 1;

FIG. 6 is a plan view illustrating the loading operation of FIG. 1;

FIG. 7A is a plan view illustrating the alignment of a first teaching point and a laser pointer, and FIG. 7B is an enlarged view of a portion AA of FIG. 7A;

FIG. 8 is a plan view illustrating first teaching points of multiple display materials having different areas;

FIG. 9 is a flowchart of a primary rotation operation of FIG. 1;

FIG. 10A is a perspective view illustrating an embodiment showing how to align a laser pointer of a loader robot according to the disclosure with a second teaching point of a rotation table, and FIG. 10B is an enlarged view of a portion BB of FIG. 10A;

FIG. 11 is a plan view illustrating an embodiment showing how to align the laser pointer of the loader robot according to the disclosure with the second teaching point of the rotation table;

FIG. 12 is a plan view illustrating the alignment of the laser pointer of FIGS. 10A and 10B with the second teaching point;

FIG. 13 is a plan view illustrating an arrangement-on-rotation-table operation of the primary rotation operation of FIG. 9;

FIG. 14 is a flowchart of a pre-alignment operation of FIG. 1;

FIG. 15 is a plan view of an embodiment of a pre-alignment table according to the disclosure;

FIG. 16 is a plan view illustrating an arrangement-on-pre-alignment-table operation of FIG. 14;

FIG. 17 is a cross-sectional view taken along line II-II′ of FIG. 16;

FIG. 18 is a plan view of an embodiment of a pre-alignment table according to the disclosure; and

FIG. 19 is a cross-sectional view taken along line III-III′ of FIG. 18.

### DETAILED DESCRIPTION

Advantages and features of the invention and methods of accomplishing the same may be understood more readily by reference to the following detailed description of embodiments and the accompanying drawings. Embodiments of the disclosure may, however, be embodied in many different forms and should not be construed as being limited to the embodiments set forth herein. Rather, these embodiments are provided so that this disclosure will be thorough and complete and will fully convey the concept of the invention to those skilled in the art, and the invention will only be defined by the appended claims.

It will be understood that when an element or layer is referred to as being “on” another element or layer, it can be directly on the other element or layer or intervening elements or layers may be present. Like reference numerals refer to like elements throughout the specification.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Features of each embodiment of the invention may be partially or coupled or combined, in part or as a whole, with one another, may be technically linked and driven in various manners, and embodiments of the invention may be implemented independently of one another or together in connection with one another.

Embodiments of the invention will hereinafter be described with reference to the accompanying drawings.

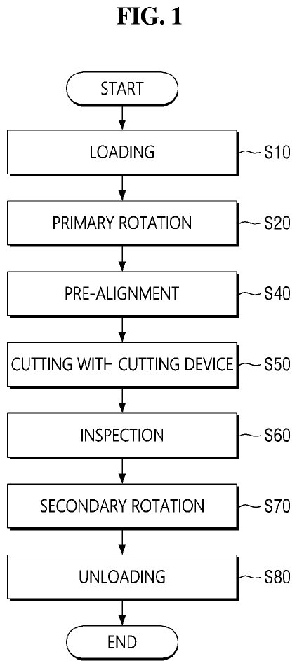

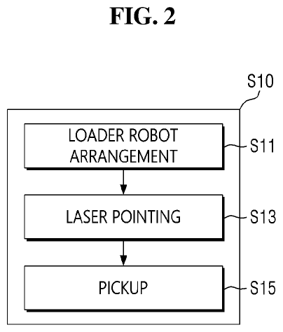

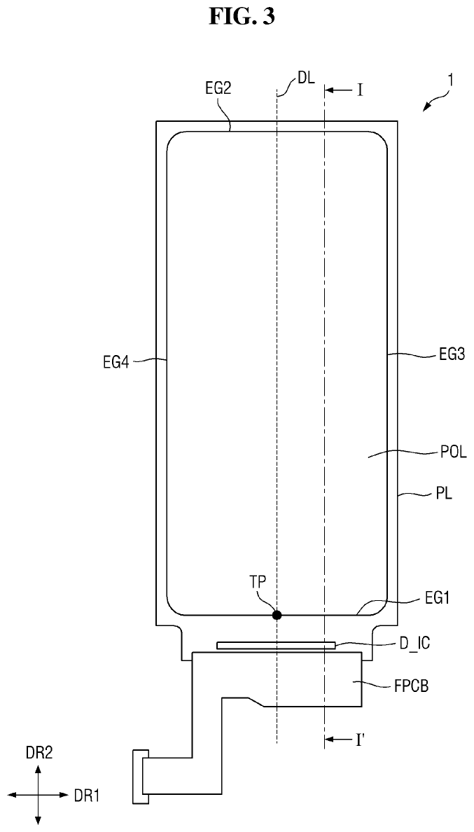

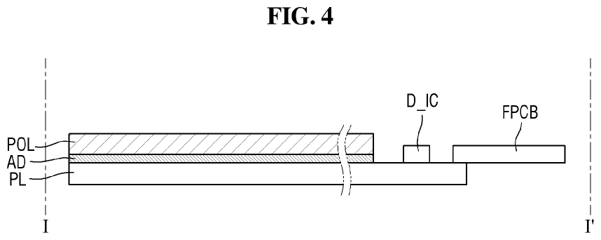

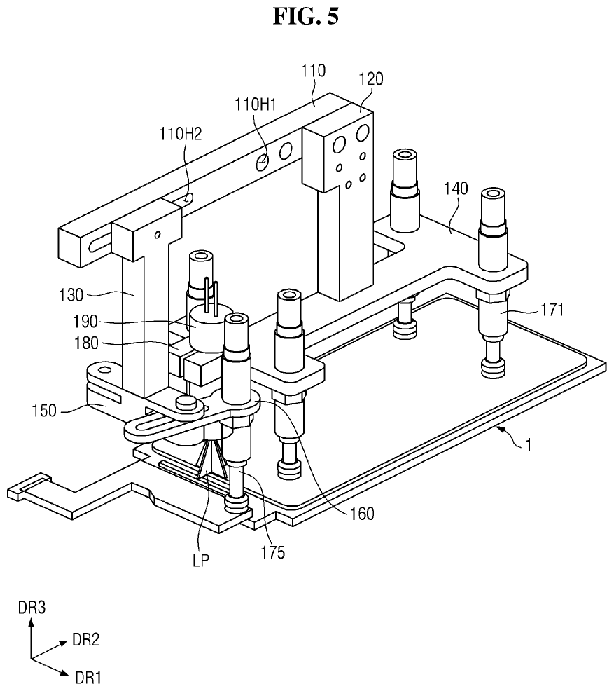

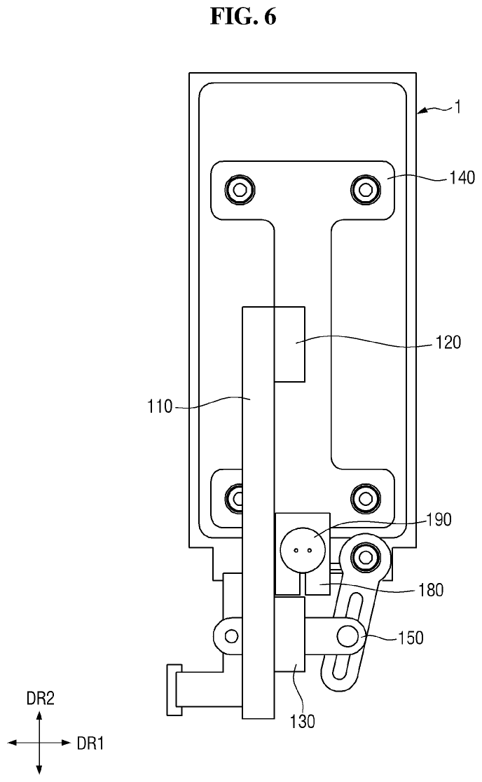

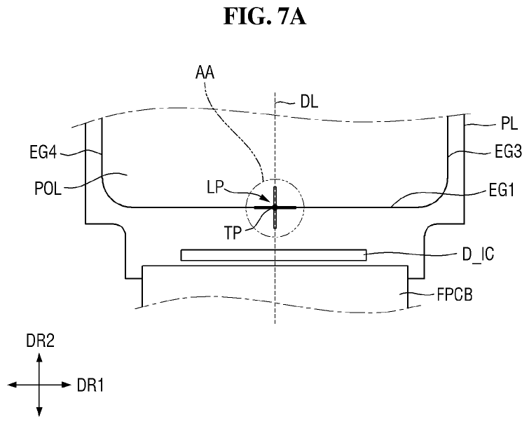

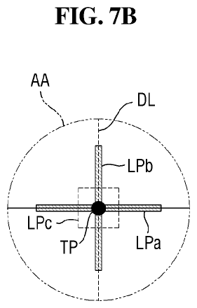

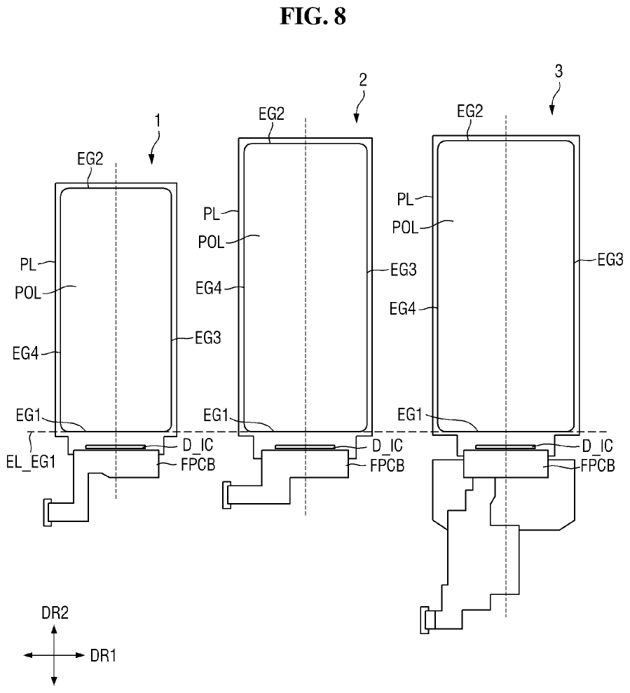

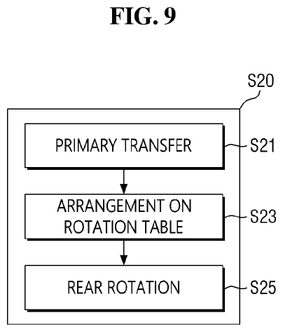

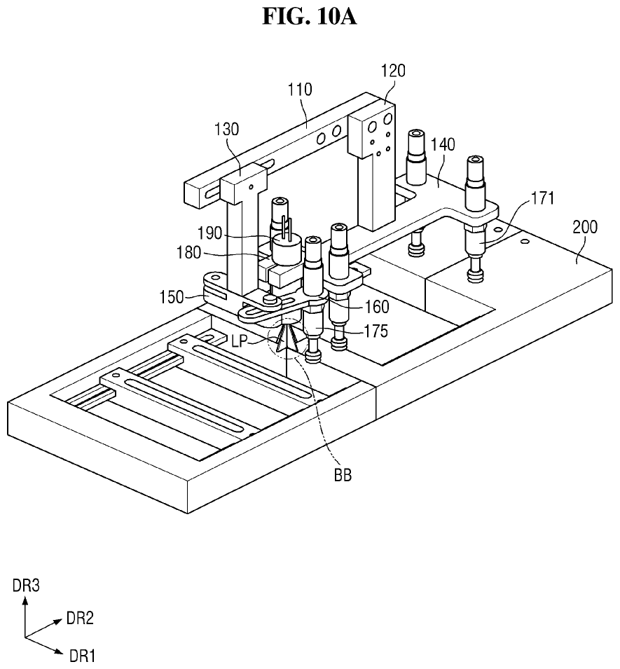

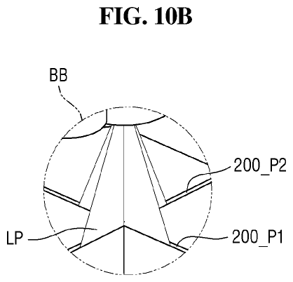

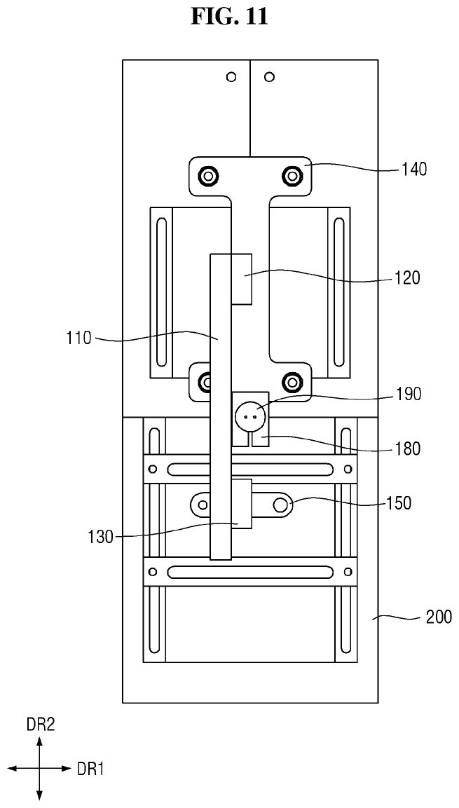

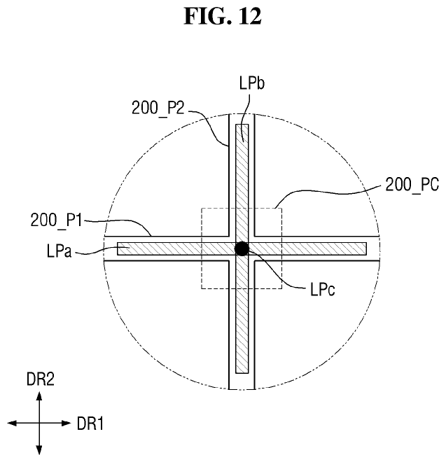

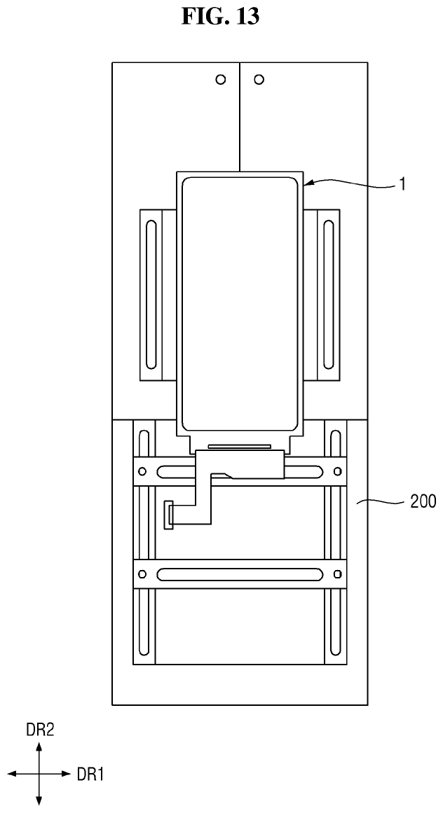

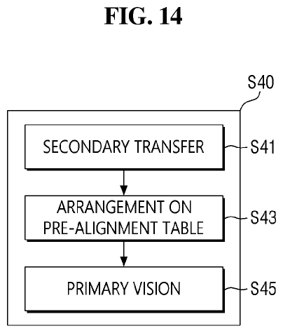

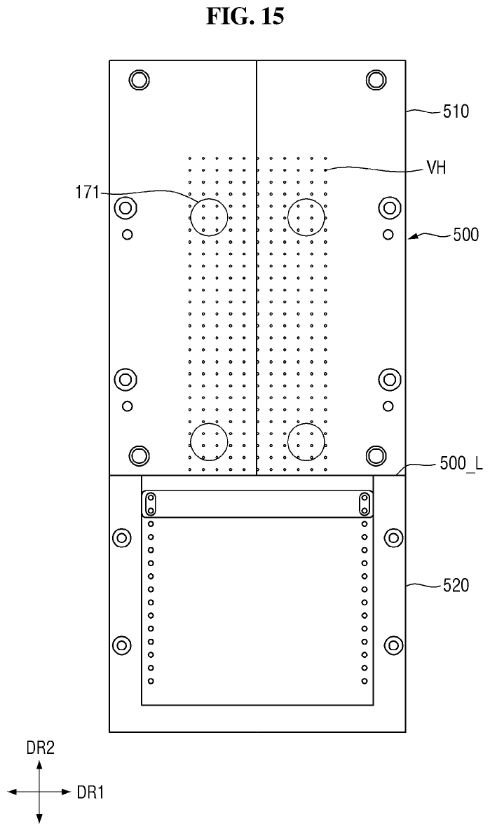

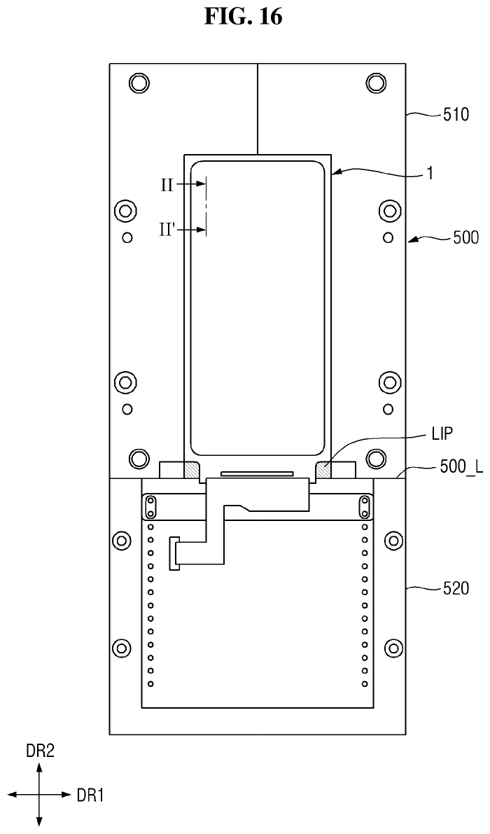

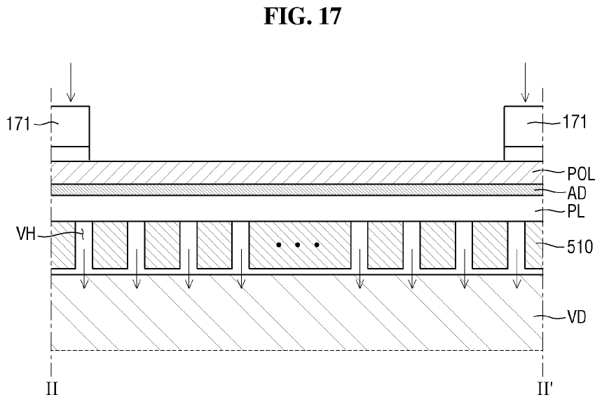

FIG. 1 is a flowchart of an embodiment of a method of laser-cutting display materials according to the disclosure. FIG. 2 is a flowchart of a loading operation of FIG. 1. FIG. 3 is a plan view of an embodiment of a display material according to the disclosure. FIG. 4 is a cross-sectional view taken along line I-I′ of FIG. 3. FIG. 5 is a perspective view illustrating the loading operation of FIG. 1. FIG. 6 is a plan view illustrating the loading operation of FIG. 1. FIG. 7A is a plan view illustrating the alignment of a first teaching point and a laser pointer, and FIG. 7B is an enlarged view of a portion AA of FIG. 7A. FIG. 8 is a plan view illustrating first teaching points of multiple display materials having different areas. FIG. 9 is a flowchart of a primary rotation operation of FIG. 1. FIG. 10A is a perspective view illustrating an embodiment sowing how to align a laser pointer of a loader robot according to the disclosure with a second teaching point of a rotation table, and FIG. 10B is an enlarged view of a portion BB of FIG. 10A. FIG. 11 is a plan view illustrating an embodiment showing how to align the laser pointer of the loader robot according to the disclosure with the second teaching point of the rotation table. FIG. 12 is a plan view illustrating the alignment of the laser pointer of FIGS. 10A and 10B with the second teaching point. FIG. 13 is a plan view illustrating an arrangement-on-rotation-table operation of the primary rotation operation of FIG. 9. FIG. 14 is a flowchart of a pre-alignment operation of FIG. 1. FIG. 15 is a plan view of an embodiment of a pre-alignment table according to the disclosure. FIG. 16 is a plan view illustrating an arrangement-on-pre-alignment-table operation of FIG. 14. FIG. 17 is a cross-sectional view taken along line II-II′ of FIG. 16.

Referring to FIGS. 1 through 17, a method of laser-cutting display materials in an embodiment of the disclosure is a method of laser-cutting a display panel PL of a display device, a polarizer member POL, which is on the display panel PL, a driver integrated circuit D_IC, which is disposed (e.g., mounted) on a part of the display panel PL that protrudes beyond the polarizer member POL in a plan view, and a printed circuit film FPCB, which is formed on one end portion of the display panel PL to conform to the shape of a display device to be shipped. The method of laser-cutting display materials may be performed by a device for laser-cutting display materials. As will be described later, the method of laser-cutting display materials may include a rotation device, which includes a tray, a loader robot, and a rotation table 200, a pre-alignment device, which includes a pre-alignment table 500, a backlight unit, primary and secondary vision cameras, and a controller.

The method of laser-cutting display materials includes a loading operation S10 of loading a display material 1 from the tray; and a cutting operation S50 of cutting a dummy portion of the loaded display material 1.

The loading operation S10 may include a loader robot arrangement operation S11 of arranging a loader robot (refer to FIG. 5) near the tray; a laser pointing operation S13 of aligning a laser pointer LP emitted from the loader robot with a first teaching point TP of the display material 1; and a pickup operation S15 of picking up the display material 1 via at least one pickup pad (171 and 175) of the loader robot. In the pickup operation S15, the pickup pads (171 and 175) may pick up the display material 1 with a predetermined pressure.

As illustrated in FIG. 3, the display material 1 may include the display panel PL and the polarizer member POL, which is disposed on the display panel PL. In an embodiment, an adhesive layer AD may be interposed between the display panel PL and the polarizer member POL.

The display panel PL may be, e.g., a light-emitting diode (“LED”) display panel, an organic light-emitting display panel, a quantum-dot light-emitting display panel, a plasma display panel, or a field emission display panel. The display panel PL will hereinafter be described as being, e.g., an LED display panel, but the disclosure is not limited thereto. That is, the disclosure may also be applicable to various other display panels.

The display panel PL may have a quadrangular shape, e.g., rectangular shape having short sides extending in a first direction DR1 and long sides extending in a second direction DR2, which intersects the first direction DR1. The display panel PL may further include a protruding part, which protrudes from the short side, on a second side, in the second direction DR2, of the display panel PL in the second direction DR2. The width, in the first direction DR1, of the protruding part of the display panel PL may be less than the width, in the first direction DR1, of a rectangular part of the display panel PL.

The planar shape of the polarizer member POL may be generally similar to the planar shape of the rectangular part of the display panel PL. The polarizer member POL may include edges EG3 and EG4, which are adjacent to the long sides of the display panel PL, and edges EG1 and EG2, which are adjacent to the short sides of the display panel PL.

Typically, the display material 1 may be loaded from the tray by arranging the centers of the pickup pads of the loader robot in the middle of the display material 1 and lifting down the display material 1.

However, as the pickup positions of the pickup pads for the display material 1 are highly likely to vary, it may take a considerable amount of time to align the display material 1 after the loading of the display material 1 (i.e., in a pre-alignment operation S40 or an inspection operation (or a fine alignment operation)).

Also, as already described above, when there are multiple display materials 1 having different sizes from each other, the middle parts of the multiple display materials 1 may not coincide with one another, and thus, it may take a considerable amount of time to calibrate the pickup positions of the multiple display materials 1.

However, according to the method of laser-cutting display materials, the loading operation S10 includes the laser pointing operation S13 of aligning the laser pointer LP emitted from the loader robot with the first teaching point TP of the display material 1 and the pickup operation S15 of picking up the display material 1 with the pickup pads (171 and 175). As the position of the laser pointer LP relative to at least one pickup pad 171 is maintained in a plan view, the pickup pads 171 whose positions relative to the laser pointer LP are maintained may be aligned with respect to the first teaching point TP by aligning the laser pointer LP with the first teaching point TP.

As the pickup positions of the pickup pads for the display material 1 are fixed, any delays in an alignment process (e.g., in the pre-alignment operation S40 or the inspection operation (or the fine alignment operation)) that follows the loading of the display material 1 may be prevented in advance.

Also, the amount of time that it takes to process multiple display materials 1 having different sizes may be considerably shortened by adopting fixed pickup positions regardless of the positions of the centers of the multiple display materials 1.

The first teaching point TP may be the intersection between the edge EG1 of the polarizer member POL, which is adjacent to the short side on the second side, in the second direction DR2, of the display panel PL, and a dividing line DL dividing the display panel PL into equal parts in the first direction DR1.

The laser pointer LP may include a first laser extension LPa, which extends in the first direction DR1, and a second laser extension LPb, which extends in the second direction DR2.

In the laser pointing operation S13, the intersection between the first and second laser extensions LPa and LPb may be aligned with the first teaching point TP. Also, the first laser extension LPa may be aligned with the edge EG1, and the second laser extension LPb may be aligned with the dividing line DL.

The cutting operation S50 may be the operation of cutting the dummy portion of the display material 1 with a cutter (also referred to as a cutting device) of the device for laser-cutting display materials.

The structure of the loader robot is as illustrated in FIGS. 5 and 6.

As illustrated in FIGS. 5 and 6, the loader robot may include a main support part 110, which extends in the second direction DR2, a first vertical part 120, which is connected to the main support part 110 and extends in a thickness direction, a second vertical part 130, which is connected to the main support part 110 and extends in the thickness direction, a first lower support part 140, which supports the first vertical part 120 from below the first vertical part 120, a second lower support part 150, which supports the second vertical part 130 from below the second vertical part 130, a plurality of pickup pads (171 and 175), which are disposed on the bottom surface of the first lower support part 140 and/or on the bottom surface of the second lower support part 150 and pick up the display material 1, a laser irradiation part fixing member 180, which is connected to the first lower support part 140 and fixes a laser irradiation part 190, and the laser irradiation part 190, which is fixed by the laser irradiation part fixing member 180.

The main support part 110 may define a plurality of fixing holes (110H1 and 110H2), which penetrate the main support part 110 in the first direction DR1. The width, in the first direction DR1, of first fixing holes 110H1 may be less than the width, in the first direction DR1, of a second fixing hole 110H2. A plurality of first fixing holes 110H1 may be defined, but the disclosure is not limited thereto. Protrusions (not illustrated) of the first vertical part 120 may be inserted in the first fixing holes 110H1. A protrusion (not illustrated) of the second vertical part 130 may be inserted in the second fixing hole 110H2. The width, in the first direction DR1, of the second fixing hole 110H2 may be greater than the width, in the first direction DR1, of the first fixing holes 110H1 to provide space in which the protrusion of the second vertical part 130 may move. That is, the first vertical part 120 may not be able to move in the second direction DR2 because it is fixed to the main support part 110 through the first fixing holes 110H1, but the second vertical part 130 is not fixed and may thus be able to move in the second direction DR2, even when the protrusion of the second vertical part 130 is inserted in the second fixing hole 110H2.

Accordingly, the first lower support part 140, which is connected to the first vertical part 120, and the first pickup pads 171, which are disposed on the bottom surface of the first lower support part 140, may both be fixed not to be movable, but the second lower support part 150, which is connected to the second vertical part 130, and a second pickup pad 175, which is disposed on the bottom surface of an auxiliary second lower support part 160, may both be movable in the second direction DR2.

The display material 1 may further include the printed circuit film FPCB, which is attached to an end portion of the display panel PL, and in the pickup operation S15, at least one of the pickup pads (171 and 175) may overlap with the display panel PL in the thickness direction and perform a pickup operation, and another one of the pickup pads (171 and 175) may overlap with the printed circuit film FPCB and perform a pickup operation.

As already described above, as the second pickup pad 175, which is disposed on the bottom surface of the second lower support part 150, is movable in the second direction DR2, the printed circuit film FPCB may be picked up by adjusting the position of the second pickup pad 175 in accordance with the size of the printed circuit film FPCB.

As illustrated in FIG. 8, according to the method of laser-cutting display materials, the amount of time that it takes to process multiple display materials 1, 2 and 3 having different sizes may be considerably shortened by adopting fixed pickup positions (e.g., intersections TP between an extension EL_EG1 of the edge EG1 of the polarizer member POL and dividing lines DL dividing each of the multiple display materials 1, 2 and 3 into equal parts) regardless of the positions of the centers of the multiple display materials 1, 2 and 3.

Thereafter, the method of laser-cutting display materials may further include, between the loading operation S10 and the cutting operation S50, a primary rotation operation S20 of reversing the loaded display material 1 in a front-to-rear direction.

The primary rotation operation S20 may include a primary transfer operation S21 of transferring the picked-up display material 1, an arrangement-on-rotation-table operation S23 of arranging the transferred display material 1 on the rotation table 200, and a rear rotation operation S25 of rotating the display material 1 disposed on the rotation table 200.

The method of laser-cutting display materials may further include, before the loader robot arrangement operation S11, the operation of aligning the laser pointer LP of the loader robot with a second teaching point 200_PC of the rotation table 200.

The second teaching point 200_PC may be provided in an engraved form on the rotation table 200.

Specifically, the second teaching point 200_PC may include a first teaching extension 200_P1, which extends in the first direction DR1, and a second teaching extension 200_P2, which extends in the second direction DR2.

In the operation of aligning the laser pointer LP with the second teaching point 200_PC of the rotation table 200, an intersection 200_PC between the first and second teaching extensions 200_P1 and 200_P2 may be aligned with an intersection LPc between the first and second laser extensions LPa and LPb. Also, the first laser extension LPa may be aligned with the first teaching extension 200_P1, and the second laser extension LPb may be aligned with the second teaching extension 200_P2.

According to the method of laser-cutting display materials, the intersection 200_PC between the first and second teaching extensions 200_P1 and 200_P2 and the intersection LPc between the first and second laser extensions LPa and LPb may be aligned in advance with each other, between the rotation table 200 and the loader robot, in the absence of the display material 1, and the pickup position of the loader robot for the display material 1 may be fixed. Accordingly, a desired level of alignment between the display material 1 and the rotation table 200 may be achieved in operations ranging from the loading operation S10 to the primary rotation operation S20.

Thereafter, the method of laser-cutting display materials may further include, between the primary rotation operation S20 and the cutting operation S50, the pre-alignment operation S40 of acquiring alignment information regarding the display material 1.

The pre-alignment operation S40 may include a second transfer operation S41 of transferring the primarily-rotated display material 1, an arrangement-on-pre-alignment-table operation S43 of arranging the transferred display material 1 on the pre-alignment table 500, and a primary vision operation S45 of capturing an image of alignment marks LIP, which are disposed on the pre-alignment table 500, by applying light via a backlight unit. In the arrangement-on-pre-alignment-table operation S43, a part of the display material 1 that overlaps with the polarizer member POL may be disposed on an upper part 510 of the pre-alignment table 500, and a part of the display material 1 that does not overlap with the polarizer member POL may be disposed on a lower part 520 of the pre-alignment table 500. A boundary 500_L between the upper and lower parts 510 and 520 of the pre-alignment table 500 may extend in the first direction DR1 and may be parallel to the first teaching extension 200_P1.

Alignment information regarding the display material 1, acquired in the primary vision operation S45, may be reflected in the cutting operation S50.

Thereafter, referring to FIG. 1, the method of laser-cutting display materials may further include, after the cutting operation S50, an inspection operation S60 of acquiring alignment information regarding the display material 1, a secondary rotation operation S70 of reversing the display material 1 in the front-to-rear direction, and an unloading operation S80 of unloading the secondarily-rotated display material 1.

The inspection operation S60 may include operations similar operations to those of the pre-alignment operation S40. The inspection operation S60 may include a third transfer operation of transferring the cut display material 1, an operation of arranging the transferred display material on an inspection table, and a secondary vision operation of capturing an image of alignment marks on the inspection table by applying light via the backlight unit. The inspection operation S60 may acquire alignment information regarding the display material 1 that has been subject to the cutting operation S50, and may adjust the position of the display material 1 based on the alignment information regarding the display material 1, acquired in the secondary vision operation.

The secondary rotation operation S70 may include a fourth transfer operation of transferring the inspected display material 1, an operation of arranging the transferred display material 1 on a secondary rotation table, and a front rotation operation of rotating the display material 1 arranged on the secondary rotation table.

The unloading operation S80 is almost similar to the loading operation S10 except that the display material 1 is picked up from the secondary rotation table, rather than from the tray.

As illustrated in FIGS. 15 through 17, a plurality of vacuum holes VH, which penetrate the pre-alignment table 500 in the thickness direction, may be defined in the upper part 510 of the pre-alignment table 500.

The vacuum holes VH, which penetrate the upper part 510 of the pre-alignment table 500, may define air passages for the air sucked by a suction device VD and may thus allow the display material 1 to be easily arranged on the pre-alignment table 500 in the operation S43 of arranging the display material 1 on the pre-alignment table 500.

As illustrated in FIG. 15, in a plan view, the vacuum holes VH may be defined in the entirety of the surface of the upper part 510. The vacuum holes VH may be arranged in a matrix, but the disclosure is not limited thereto.

Although not specifically illustrated, the device for laser-cutting display materials may further include the controller, which stores position information between the first teaching point TP of the display material 1 and the elements of the device for laser-cutting display materials. The position information may include position information between the first teaching point TP and the center of the tray, position information between the first teaching point TP and a primary rotation device, and position information between the first teaching point TP and pre-alignment marks of the pre-alignment device.

Other embodiments of the disclosure will hereinafter be described. Like reference numerals indicate like elements throughout the disclosure, and descriptions thereof will be omitted or simplified.

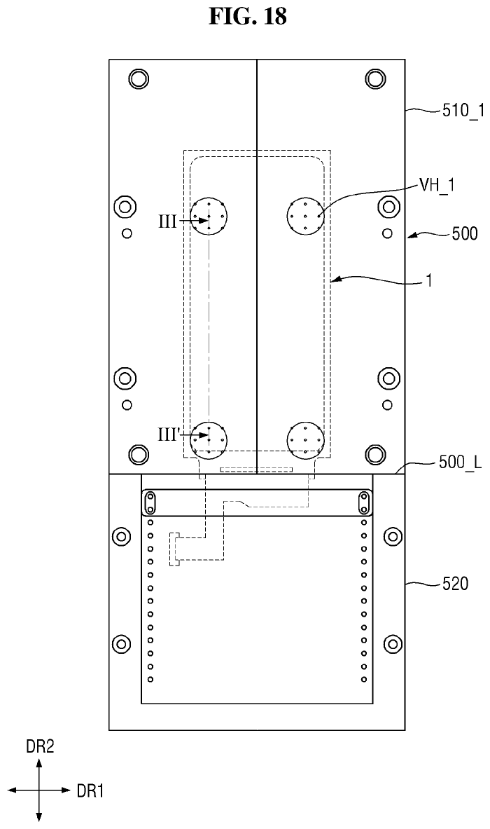

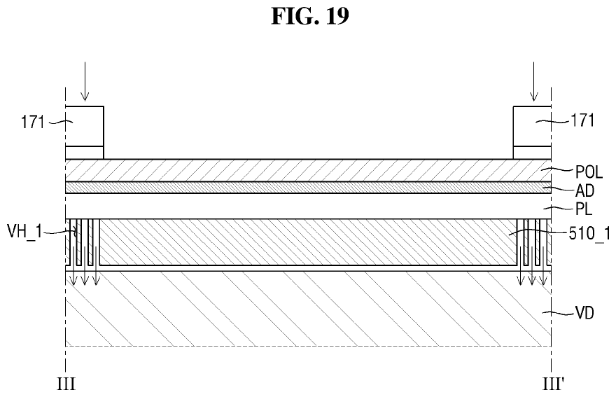

FIG. 18 is a plan view of an embodiment of a pre-alignment table according to the disclosure. FIG. 19 is a cross-sectional view taken along line III-III′ of FIG. 18.

Referring to FIGS. 18 and 19, an arrangement-on-pre-alignment-table operation differs from its counterpart of FIGS. 15 through 17 in that pickup pads 171 overlap with areas where vacuum holes VH_1 of a pre-alignment table 500 are defined.

In a method of laser-cutting display materials in the embodiment of FIGS. 18 and 19, the pickup pads 171 may overlap only with areas where vacuum holes VH_1 of the pre-alignment table 500 are defined, in the arrangement-on-pre-alignment-table operation. That is, the vacuum holes VH_1 of an upper part 510_1 of the pre-alignment table 500, unlike the vacuum holes VH of FIGS. 15 through 17, may not be defined in the entirety of the surface of the pre-alignment table 500, but defined only locally in the pre-alignment table 500.

In the method of laser-cutting display materials in the embodiment of FIGS. 18 and 19, the vacuum holes VH_1 may not be defined in the entirety of the surface of the pre-alignment table 500, but may be formed locally at locations overlapping with the pickup pads 171, in the arrangement-on-pre-alignment-table operation. Accordingly, the display material 1 may be effectively separated from the pickup pads 171, which fix the display material 1 with a predetermined pressure, and the display material 1 may be prevented in advance from being bent or physically damaged in all areas overlapping with the vacuum holes VH_1, except for areas picked up by the pickup pads 171.

Although a few embodiments of the invention have been described, those skilled in the art will readily appreciate that many modifications are possible in the embodiments without departing from the novel teachings and advantages of the invention. Accordingly, all such modifications are intended to be included within the scope of the invention as defined in the claims. Therefore, it is to be understood that the foregoing is illustrative of the invention and is not to be construed as limited to the illustrative embodiments disclosed.

1. A method of laser-cutting display materials, comprising:
loading display materials from a tray,
wherein the loading the display materials includes:
arranging a loader robot near the tray,
aligning pickup pads of the loader robot with the display materials, and
picking up the display materials with the pickup pads of the loader robot,
wherein in the aligning the pickup pads, pickup pads are aligned with the display materials in accordance with the same standard regardless of a size of the display materials, and
wherein in the picking up the display materials, the pickup pads pick up the display materials regardless of center positions of the display materials.

2. The method of claim 1, wherein the aligning the pickup pads includes aligning a laser pointer emitted from the loader robot with a first teaching point of each of the display materials.

3. The method of claim 2, wherein
each of the display materials includes a display panel which displays an image, and a polarizer member which is disposed on the display panel, and
the first teaching point is an intersection between a dividing line dividing the display panel into equal parts and an edge of the polarizer member.

4. The method of claim 3, wherein
the display panel includes a rectangular shape formed by short sides extending in a first direction and long sides extending in a second direction intersecting the first direction, and
the first teaching point is an intersection between the edge of the polarizer member adjacent to one of the short sides of the display panel and the dividing line dividing the display panel into equal parts in the first direction.

5. The method of claim 3, wherein
the laser pointer includes a first laser extension which extends in a first direction, and a second laser extension which extends in a second direction intersecting the first direction, and
in the aligning the laser pointer, an intersection between the first laser extension and the second laser extension is aligned with the first teaching point.

6. The method of claim 5, further comprising:
cutting the display materials; and
between the loading the display materials and the cutting the display materials,
reversing the loaded display materials in a front-to-rear direction.

7. The method of claim 6, wherein the reversing the loaded display materials comprises:
transferring the picked-up display materials,
arranging the transferred display materials on a rotation table, and
rotating the display materials arranged on the rotation table.

8. The method of claim 7, further comprising, before the arranging the transferred display materials:
aligning the laser pointer of the loader robot with a second teaching point of the rotation table.

9. The method of claim 8, wherein the second teaching point is provided in an engraved form on the rotation table.

10. The method of claim 9, wherein
the second teaching point includes a first teaching extension which extends in the first direction, and a second teaching extension which extends in the second direction, and
in the aligning the laser pointer of the loader robot with the second teaching point of the rotation table, an intersection between the first teaching extension and the second teaching extension is aligned with the intersection between the first laser extension and the second laser extension.

11. The method of claim 7, further comprising, between the reversing the loaded display materials and the cutting the display materials:
acquiring alignment information regarding the display materials.

12. The method of claim 11, wherein the acquiring alignment information includes:
transferring the primarily-rotated display materials,
arranging the transferred display materials on a pre-alignment table, and
capturing an image of alignment marks on the pre-alignment table by applying light via a backlight unit,
wherein the method further comprises cutting dummy portions of the loaded display materials, and
wherein the alignment information regarding the display materials, acquired in the capturing the image of the alignment marks, is reflected in the cutting the dummy portions.

13. The method of claim 12, further comprising, after the cutting the dummy portions:
acquiring alignment information regarding the display materials;
reversing the display materials in the front-to-rear direction after the acquiring alignment information; and
unloading the secondarily-rotated display materials.

14. The method of claim 12, wherein in the arranging the transferred display materials on the pre-alignment table, the pickup pads overlap with areas where vacuum holes of the pre-alignment table are defined.

15. The method of claim 3, wherein
each of the display materials further includes a printed circuit film which is attached to an end portion of the display panel,
and
in the picking up the display material, at least one of the pickup pads picks up the display panel, overlapping with the display panel in a thickness direction, and another one of the pickup pads picks up the printed circuit film, overlapping with the printed circuit film in the thickness direction.

16. The method of claim 15, wherein
a pickup pad of the pickup pads picking up the printed circuit film is movable in one direction.

17. The method of claim 3, wherein in a plan view, positions of the laser pointer and the pickup pads relative to one another are maintained.

18. A device for laser-cutting display materials, the device comprising:
a tray in which display materials are loaded; and
a loader robot which loads the display materials from the tray,
the loader robot including
a laser irradiation part, which irradiates a laser pointer to be aligned with first teaching points of the display materials; and
pickup pads, which pick up the display materials.

19. The device of claim 18, wherein
the laser pointer includes a first laser extension, which extends in a first direction, and a second laser extension, which extends in a second direction intersecting the first direction, and
when the laser pointer is emitted, an intersection between the first laser extension and the second laser extension is aligned with each of the first teaching points.

20. The device of claim 19, further comprising:
a cutting device;
a primary rotation device which rotates the loaded display materials in a front-to-rear direction, ahead of the cutting device;
a rotation table of the primary rotation device includes a second teaching point, which is provided in an engraved form to be aligned with the laser pointer of the loader robot before the loading of the display materials,
the second teaching point includes a first teaching extension, which extends in the first direction, and a second teaching extension, which extends in the second direction, and
when the second teaching point of the rotation table is aligned with the laser pointer, an intersection between the first teaching extension and the second teaching extension is aligned with the intersection between the first laser extension and the second laser extension.

21. The device of claim 20, further comprising, between the primary rotation device and the cutting device:
a pre-alignment device which acquires alignment information regarding the display materials.

22. The device of claim 21, wherein
the cutting device cuts dummy portions of the loaded display materials.

23. A device for laser-cutting display materials, comprising:
a tray in which display materials are loaded;
a loader robot which loads the display materials from the tray; and
a pre-alignment device which acquires alignment information regarding the display materials,
wherein
the loader robot includes pickup pads, which pick up the display materials,
a pre-alignment table of the pre-alignment device defines vacuum holes, and
when each of the display materials is disposed on the pre-alignment table, the pickup pads overlap with areas where the vacuum holes of the pre-alignment table are defined.

24. The device of claim 23, further comprising:
a cutting device which cuts dummy portions of the loaded display materials; and
a primary rotation device which reverses the loaded display materials in a front-to-rear direction, ahead of the cutting device,
wherein the pre-alignment device is disposed between the primary rotation device and the cutting device.
